(19) United States
(12) Patent Application Publication
(10) Pub. No.: US 2014/0145327 A1
(43) Pub. Date: May 29, 2014

(54) SEMICONDUCTOR DEVICE AND METHOD FOR FABRICATING THE SAME

(71) Applicant: Samsung Electronics Co., Ltd., Suwon-Si (KR)

(72) Inventors: Hyung-Jun JEON, Seoul (KR); Jae-Hyun PHEE, Incheon (KR); Byung-Lyul PARK, Seoul (KR); Ji-Soon PARK, Suwon-si (KR); Jeong-Gi JIN, Osan-si (KR)

(73) Assignee: SAMSUNG ELECTRONICS CO., LTD., Suwon-Si (KR)

(21) Appl. No.: 14/060,913

(22) Filed: Oct. 23, 2013

(30) Foreign Application Priority Data
Nov. 26, 2012 (KR) 10-2012-0134529

(51) Int. Cl. H01L 23/00

(52) U.S. Cl. CPC H01L 24/12
USPC 257/737

(57) ABSTRACT

Semiconductor devices and methods for fabricating the same are provided. For example, the semiconductor device includes a substrate, a first contact pad formed on the substrate, an insulation layer formed on the substrate and including a first opening which exposes the first contact pad, a first bump formed on the first contact pad and electrically connected to the first contact pad, and a reinforcement member formed on the insulation layer and adjacent to a side surface of the first lower bump. The first bump includes a first lower bump and a first upper bump, which are sequentially stacked on the first contact pad.

### CROSS-REFERENCE TO RELATED APPLICATION

This application claims priority under 35 U.S.C. 119 to Korean Patent Application No. 10-2012-0134529, filed on Nov. 26, 2012, in the Korean Intellectual Property Office, the contents of which in its entirety are herein incorporated by reference.

### BACKGROUND

1. Field

Example embodiments of the inventive concepts relate to semiconductor devices and/or methods for fabricating the same.

2. Description of the Related Art

Recently, as a semiconductor device has become lighter, thinner, and smaller, an external terminal that connects the semiconductor device to an external power source or another semiconductor device is also being reduced in size. Stable implementation of the external terminal helps achieve a reliable semiconductor package fabricated using a semiconductor device. Accordingly, in order to improve the reliability an external terminal through which electrical signals are exchanged between the semiconductor device and an external device, various studies are being conducted.

### SUMMARY

Example embodiments of the inventive concepts provide semiconductor devices, which can improve reliability of a micro bump by using a reinforcement member formed around the micro bump.

Example embodiments of the inventive concepts also provide methods for fabricating a semiconductor device, which can improve reliability of a micro-bump by using a reinforcement member formed around the micro-bump.

These and other features of example embodiment will be described in or be apparent from the following description.

According to example embodiments, a semiconductor device may include a substrate, a first contact pad formed on one surface of the substrate, an insulation layer formed on one surface of the substrate, the insulation layer including a first opening exposing the first contact pad, a first bump formed on the first contact pad and electrically connected to the first contact pad, the first bump including a first lower bump and a first upper bump sequentially stacked on the first contact pad, and a reinforcement member formed on the insulation layer and formed on, or adjacent to, a side surface of the first lower bump.

According to example embodiments, a semiconductor device may include a substrate, a contact pad formed on one surface of the substrate, a bump formed on the contact pad, a conductive pattern interposed between the contact pad and the bump, the conductive pattern having a portion exposed from the bump, and a reinforcement member formed on the exposed portion of the conductive pattern and formed at a lower portion of a side surface of the lower bump.

According to example embodiments, a semiconductor device may include a contact pad on a substrate, an insulation layer on a substrate, the insulation layer including an opening which exposes the contact pad, a bump electrically connecting the contact pad through the opening, a reinforcement member on the insulation layer, the reinforcement layer adjacent to a side surface of the bump and on the insulation layer.

The semiconductor device may further include a conductive pattern under the reinforcement member and along the insulation layer and the opening. The conductive pattern may include a non-overlap portion with respect to the reinforcement member. Accordingly, the reinforcement member may be on the non-overlap portion of the conductive pattern.

The semiconductor device may further include a conductive pattern under the reinforcement member and along the insulation layer and the opening and the conductive pattern may define an undercut region in association with the bump and insulating layer.

The bump may include a lower bump and an upper bump, and the reinforcement member may be adjacent to at least a lower portion of a side surface of the lower bump.

The lower bump may include a first part filling the opening and a second part on the first part. The first and second parts may be defined with respect to an upper surface of the insulation layer. The reinforcement member may be adjacent to at least a lower portion of a side surface of the second part.

### BRIEF DESCRIPTION OF THE DRAWINGS

The above and other features and advantages of example embodiments will become more apparent by describing with reference to the attached drawings in which:

FIG. 1 is a plan view illustrating a portion of a semiconductor device according to example embodiments;

FIG. 2 is a cross-sectional view taken along the line II-II′ of FIG. 1;

FIGS. 3A and 3B are enlarged views illustrating a portion III of FIG. 2 for explaining modified examples of the semiconductor device shown in FIG. 1, and FIG. 3C is a plan view of a bump shown in FIG. 3B;

FIG. 4 is a plan view illustrating a portion of a semiconductor device according to other example embodiments;

FIG. 5 is a plan view illustrating a portion of a semiconductor device according to still other example embodiments;

FIG. 6 is a plan view illustrating a portion of a semiconductor device according to even other example embodiments;

FIG. 7 illustrates a state in which semiconductor devices according to example embodiments are adhered to different substrates;

FIG. 8 is a perspective view of an electronic device including semiconductor devices manufactured according to various example embodiments;

FIGS. 9 to 14 illustrate intermediate process steps for explaining a method for fabricating a semiconductor device according to example embodiments; and

FIGS. 15 to 17 illustrate intermediate process steps for explaining a method for fabricating a semiconductor device according to other example embodiments.

### DETAILED DESCRIPTION

Example embodiment will now be described more fully hereinafter with reference to the accompanying drawings. Example embodiments may, however, be embodied in different forms and should not be construed as limited to the example embodiments set forth herein. Rather, example embodiments are provided so that this disclosure will be thorough and complete, and will filly convey the scope of the inventive concepts to those skilled in the art. The same reference numbers indicate the same components throughout the specification. In the attached figures, the thicknesses of layers and regions are exaggerated for clarity.

It will be understood that when an element or layer is referred to as being “connected to,” or “coupled to” another element or layer, it can be directly connected to or coupled to another element or layer or intervening elements or layers may be present. In contrast, when an element is referred to as being “directly connected to” or “directly coupled to” another element or layer, there are no intervening elements or layers present. Like numbers refer to like elements throughout. As used herein, the term “and/or” includes any and all combinations of one or more of the associated listed items.

It will also be understood that when a layer is referred to as being “on” another layer or substrate, it can be directly on the other layer or substrate, or intervening layers may also be present. In contrast, when an element is referred to as being “directly on” another element, there are no intervening elements present.

It will be understood that, although the terms first, second, etc. may be used herein to describe various elements, these elements should not be limited by these terms. These terms are only used to distinguish one element from another element. Thus, for example, a first element, a first component or a first section discussed below could be termed a second element, a second component or a second section without departing from the teachings of the example embodiments.

The use of the terms “a” and “an” and “the” and similar referents in the context of describing the example embodiments (especially in the context of the following claims) are to be construed to cover both the singular and the plural, unless otherwise indicated herein or clearly contradicted by context. The terms “comprising,” “having,” “including,” and “containing” are to be construed as open-ended terms (i.e., meaning “including, but not limited to,”) unless otherwise noted.

Unless defined otherwise, all technical and scientific terms used herein have the same meaning as commonly understood by one of ordinary skill in the art to which these example embodiments belong. It is noted that the use of any and all examples, or example terms provided herein is intended merely to better illuminate the example embodiments and is not a limitation on the scope of the example embodiments unless otherwise specified. Further, unless defined otherwise, all terms defined in generally used dictionaries may not be overly interpreted.

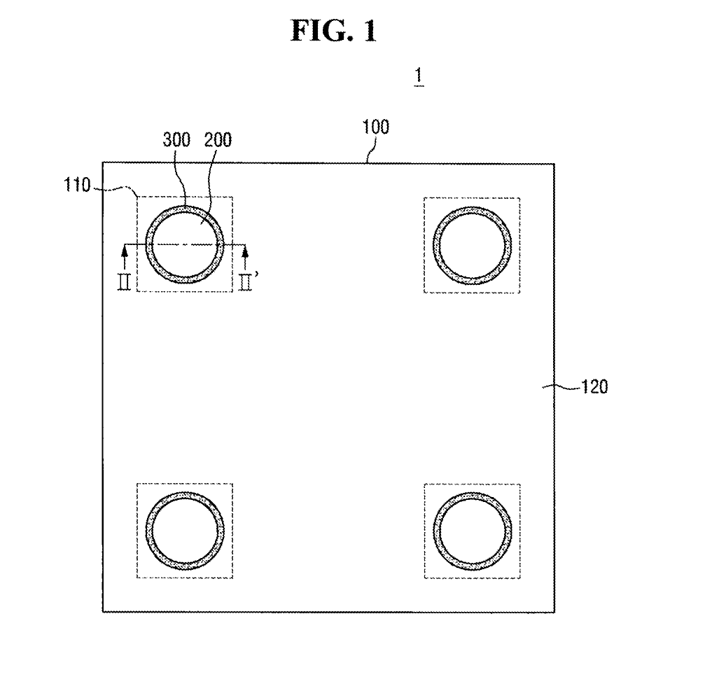

Hereinafter, a semiconductor device according to example embodiments will now be described with reference to FIGS. 1 to 3C.

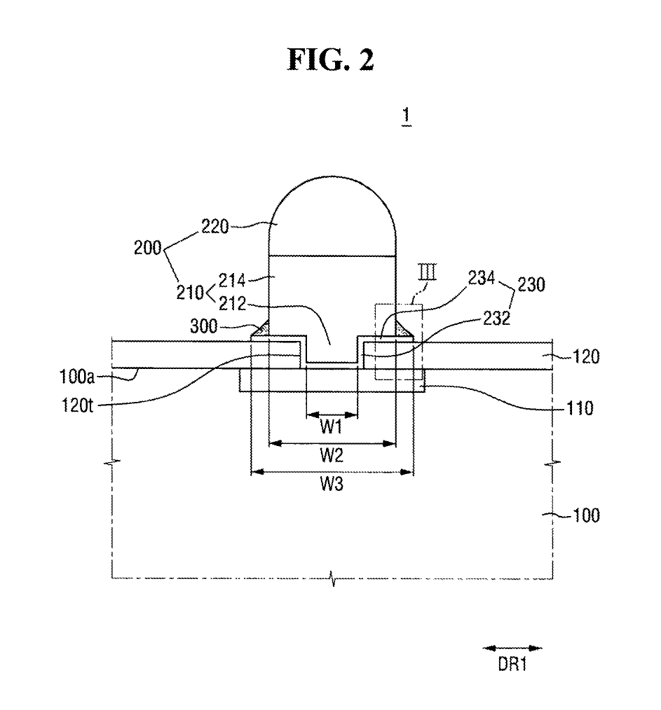

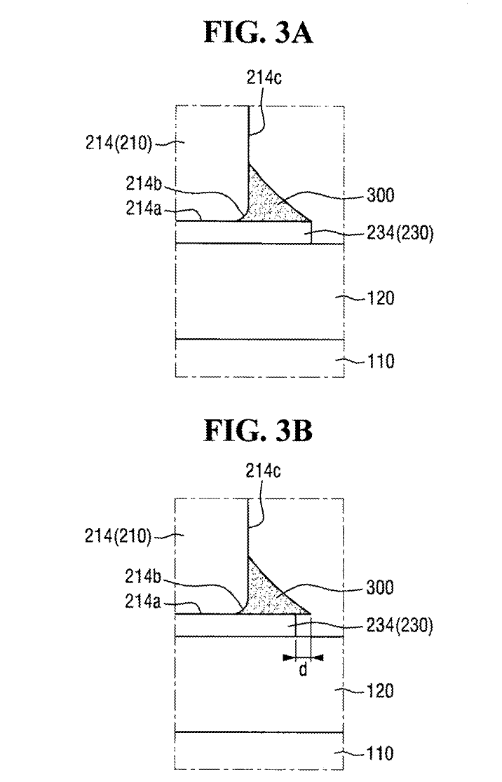

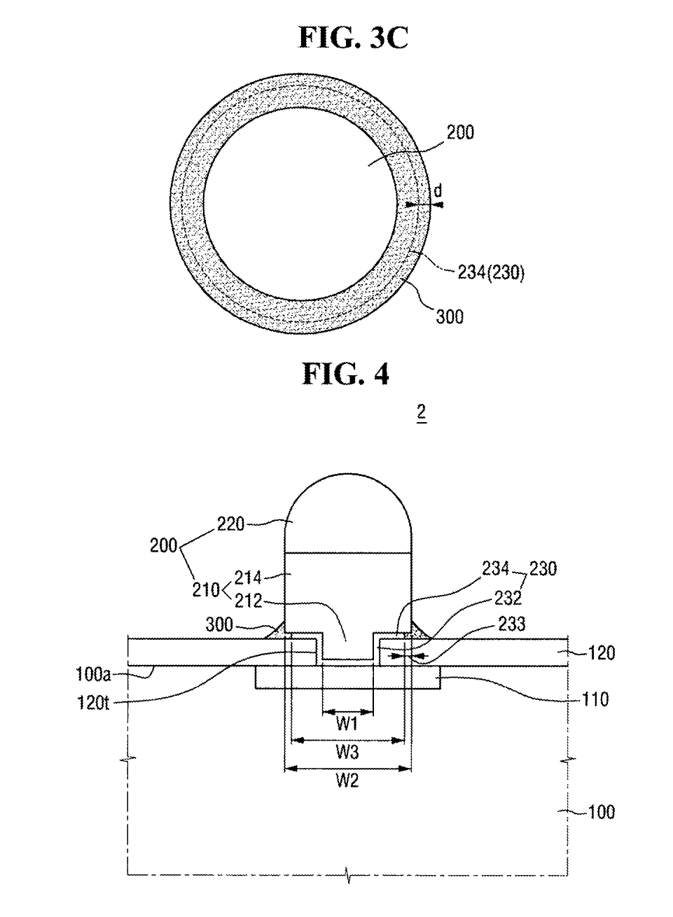

FIG. 1 is a plan view illustrating a portion of a semiconductor device according to example embodiments, FIG. 2 is a cross-sectional view taken along the line II-II′ of FIG. 1, FIGS. 3A and 3B are enlarged views illustrating a portion III of FIG. 2 for explaining modified examples of the semiconductor device shown in FIG. 1, and FIG. 3C is a plan view of a bump shown in FIG. 3B.

Referring to FIG. 1, the semiconductor device 1 may include a substrate 100, a first contact pad 110, a first bump 200 and a first reinforcement member 300.

The first contact pad 110 may be formed on one surface of the substrate 100. For example, the first contact pad 110 may be formed to slant to a corner on the one surface of the substrate 100, but example embodiments are not limited thereto.

The substrate 100 may be, for example, a wafer-based substrate, or a chip-based substrate formed by separating a wafer into multiple parts. In the latter case, the substrate 100 may include, for example, a memory chip, or a logic chip.

When the substrate 100 is a logic chip, it may be designed in various manners in consideration of operations to be performed by the logic chip. When the substrate 100 is a memory chip, the memory chip may be, for example, a non-volatile memory chip. In detail, the memory chip may be a flash memory chip. In more detail, the memory chip may be either a NAND flash memory chip or an NOR flash memory chip. However, the present inventive concepts are not limited to the type of the memory device disclosed herein. In some example embodiments, the memory chip may include one of a phase-change random access memory (PRAM), a magneto-resistive random access memory (MRAM), and a resistive random access memory (RRAM).

When the substrate 100 is a wafer-based substrate, it may include a logic device or a memory device performing the functions as described above.

An insulation layer 120 covering the substrate 100 and the first contact pad 110 may be formed over the entire surface of the substrate 100. The insulation layer 120 may cover a portion of the first contact pad 110. In order to electrically connect the first contact pad 110 to the first bump 200, the insulation layer 120 may not overlap the portion of the first contact pad 110.

The first bump 200 may be formed on the first contact pad 110. For example, the first bump 200 may be formed around the center of the first contact pad 110. As illustrated in FIG. 2, the first bump 200 may entirely overlap the first contact pad 110, but example embodiments are not limited thereto.

The first reinforcement member 300 may be formed around the first bump 200. As illustrated in FIG. 2, the first reinforcement member 300 may also be formed on the first contact pad 110, but example embodiments are not limited thereto. For example, a portion of the first reinforcement member 300 may not overlap the first contact pad 110 according to where a contact portion between the first reinforcement member 300 and the first bump 200 lies.

In FIG. 1, the first reinforcement member 300 may surround the first bump 200, and cross-sections of the first reinforcement member 300 and the first bump 200 may be concentric. For example, the first bump 200 may have a circular planar shape, and the first reinforcement member 300 may have an annular planar shape, and centers of the first bump 200 and the first reinforcement member 300 may coincide with each other. However, example embodiments are not limited by the cross-sectional shapes of the first bump 200 and the first reinforcement member 300 those disclosed herein. For example, the first bump 200 and the first reinforcement member 300 may have any cross-sectional shapes so long as the reinforcement member 300 is formed to surround the first bump 200.

Referring to FIG. 2, the semiconductor device 1 may include a substrate 100, a first contact pad 110, a first bump 200 and a first reinforcement member 300. The semiconductor device 1 may further include an insulation layer 120 and/or a first conductive pattern 230. The first bump 200 may include a first upper bump 220 and a first lower bump 210.

The first contact pad 110 may be formed on, for example, one surface 100a of the substrate 100. For instance, as illustrated in FIG. 2, the first contact pad 110 may be recessed into the one surface 100a of the substrate 100, but example embodiments are not limited thereto. For example, the first contact pad 110 may protrude on the one surface 100a of the substrate 100 and the vicinity of the first contact pad 110 may be surrounded by a passivation layer (not shown).

The first contact pad 110 may be, for example, a bonding pad that electrically connects an external terminal to a circuit pattern in the substrate 100, but example embodiments are not limited thereto. The first contact pad 110 may be a redistribution pattern or a pad formed on a through silicon via (TSV) passing through the substrate 100. The first contact pad 110 may be formed of, for example, a metal such as aluminum (Al).

The insulation layer 120 may be formed on one surface 100a of the substrate 100 and may include a first opening 120t. The first opening 120t may completely overlap the first contact pad 110 to expose the first contact pad 110. The insulation layer 120 may protect a circuit pattern disposed on the substrate 100. The insulation layer 120 may include, for example, a nitride layer or an oxide layer. Referring to FIG. 2, only the insulation layer 120 is formed on the substrate 100, but example embodiments are not limited thereto. For example, a passivation layer (not shown) may further be formed on the insulation layer 120. The passivation layer may be made of, for example, polyimide.

The first conductive pattern 230 may be formed on the insulation layer 120 and the first contact pad 110. The first conductive pattern 230 may be formed to contact the first contact pad 110. The first conductive pattern 230 may be interposed between the first bump 200 and the first contact pad 110. The first conductive pattern 230 may be conformally formed along the insulation layer 120 and the first opening 120t. The first conductive pattern 230 may include a lower portion 232 conformally covering the inner surface of the first opening 120t and an upper conductive portion 234 formed on the insulation layer 120. A portion of the first conductive pattern 230 may be exposed from, e.g., may not be overlapped by the first bump 200, and a first reinforcement member 300 may be formed on the exposed first conductive pattern 230. For example, the first reinforcement member 300 may be formed at a lower portion of the side surface of the first lower bump 210. For example, a portion of the upper conductive portion 234 may protrude from the first bump 200, and the first reinforcement member 300 may be formed on the exposed upper conductive portion 234.

The first conductive pattern 230 may be under bump metallurgy (UBM) functioning as an adhesive layer, a diffusion preventing layer and/or a wetting layer. For example, when the first bump 200 to be connected to an external terminal is directly formed on the exposed first contact pad 110, stress may be concentrated between the first contact pad 110 and the first bump 200 made of different materials. Accordingly, the first bump 200 may not be well adhered to the first contact pad 110. That is to say, because a bump material is not wetted to the first contact pad 110, the first contact pad 110 and the first bump 200 may not be adhered to each other. Even if the first contact pad 110 and the first bump 200 are adhered to each other, stress may be concentrated on a junction surface between the first contact pad 110 and the first bump 200. If the stress is concentrated on the junction surface between the first contact pad 110 and the first bump 200, the first contact pad 110 and the first bump 200 may be separated from each other during a continuous operation of a semiconductor device. Thus, the semiconductor device may be liable to a mechanical failure.

The first conductive pattern 230 may be formed to have a multi-layered structure including various metals, e.g., chrome (Cr), copper (Cu), nickel (Ni), titanium-tungsten (TiW), or nickel-vanadium (NiV). For example, the first conductive pattern 230 may have a Ti/Cu, Cr/Cr—Cu/Cu, TiW/Cu, Al/NiV/Cu or Ti/Cu/Ni structure. The first conductive pattern 230 may be used as a seed layer in a subsequent plating process.

The first bump 200 may be formed on the first contact pad 110 and may be electrically connected to the first contact pad 110. The first bump 200 may be connected to the first contact pad 110 by means of the first conductive pattern 230. A portion of the first bump 200 may be formed within the insulation layer 120, and the remaining portion of the first bump 200 may protrude on the insulation layer 120. The first reinforcement member 300 may be formed around the first bump 200.

The first bump 200 may include the first upper bump 220 and the first lower bump 210. The first lower bump 210 and the first upper bump 220 may be sequentially stacked on the first contact pad 110. The first reinforcement member 300 may be formed around the first lower bump 210 of the first bump 200. The first lower bump 210 may include various metals, for example, nickel (Ni), copper (Cu), palladium (Pd), platinum (Pt), gold (Au) or combinations thereof. The first upper bump 220 may be conductive paste, e.g., solder paste or metal paste. For example, the first upper bump 220 may be made of, e.g., a tin-silver (SnAg) alloy or tin (Sn). For example, the first lower bump 210 may be made of copper, and the first upper bump 220 may be made of a tin-silver (SnAg) alloy.

The first upper bump 220 may have, for example, a hemispherical shape, but example embodiments are not limited thereto. For example, a relationship between a height of the first upper bump 220 and one half width of the first lower bump 210 contacting the first upper bump 220 may vary according to the amount of materials forming the first upper bump 220.

of the first part 212 of the first lower bump 210 may be a first width w1, and a width of the second part 214 of the first lower bump 210 may be a second width w2. The first width w1 of the first part 212 may be smaller than a second width w2 of the second part 214. The side surface of the first lower bump 210 may have a stepped cross-section, but example embodiments are not limited thereto.

The first part 212 of the first lower bump 210 may be formed in the first opening 120t. The first part 212 of the first lower bump 210 is positioned closer to the substrate 100 than the second part 214 of the first lower bump 210. Sidewalls of the first part 212 of the first lower bump 210 may be substantially completely surrounded by the first conductive pattern 230. The second part 214 of the first lower bump 210 may be formed on the insulation layer 120. The second part 214 of the first lower bump 210 may be formed to be higher than the insulation layer 120. For example, the second part 214 of the first lower bump 210 may be formed to be higher than the upper conductive portion 234. At least a portion of the second part 214 of the first lower bump 210 may be surrounded by the first reinforcement member 300.

Referring to FIGS. 1 and 2, the first lower bump 210 may be a sequential stack of a cylinder having the width w1 of the first part 212 and a cylinder having the width w2 of the second part 214. For example, the first lower bump 210 may be a combination of pillar-shaped cylinders having the widths w1 and w2.

Referring to FIG. 2, the first conductive pattern 230 may have a width w3. The term “width” used herein may mean a width in a first direction DR1, that is, a shortest width in the first direction DR1. That is to say, while the first conductive pattern 230 is conformally formed along the insulation layer 120 and the first opening 120t, the width w3 of the first conductive pattern may mean the shortest width in the first direction DR1, irrespective of the curved shape of the first conductive pattern 230. In addition, for example, when referring to a width of component having more than one width, like in the first lower bump 210 including the first part 212 and the second part 214, the term “width” of the component may mean the largest width of the component. Accordingly, while the width of the first part 212 is w1, and the width of the second part 214 is w2, the width of the first lower bump 210 is the largest width, i.e., the width w2 of the second part 214.

The width w3 of the first conductive pattern 230 may be greater than the width w2 of the first lower bump 210. The first lower bump 210 may completely overlap the first conductive pattern 230. The width w1 of the first part 212 of the first lower bump 210, the width w2 of the first lower bump 210 and the width w3 of the first conductive pattern 230 may increase in turn.

For example, the side surface of the first lower bump 210 and the first conductive pattern 230 meet substantially at right angle and the first bump 200 and the first conductive pattern 230 have the same symmetry axis. Thus, a width of the first reinforcement member 300 may be substantially equal to a value obtained by dividing a difference between the width w3 of the first conductive pattern 230 and the width w2 of the second part 214 of the first lower bump 210 by 2, but example embodiments are not limited thereto. The first conductive pattern 230 may be undercut to a lower portion of the first reinforcement member 300, which will later be described with reference to FIG. 3B.

Referring to FIG. 2, the first reinforcement member 300 may be formed on the insulation layer 120 and may be formed on side surfaces of the first lower bump 210. For example, the first reinforcement member 300 may surround the first bump 200. The first reinforcement member 300 may be formed on the upper conductive portion 234, which is positioned on the insulation layer 120. The first reinforcement member 300 may surround the first lower bump 210 and may surround the side surfaces of the second part 214 of the first lower bump 210. The first reinforcement member 300 may contact the side surfaces of the second part 214 of the first lower bump 210 and the upper conductive portion 234 of the first conductive pattern 230.

In order to insulate the first bump 200 from other circuit patterns formed on the substrate 100, excluding electrical connection between the first bump 200 and the first contact pad 110, the first reinforcement member 300 may include an insulating material. Further, the first reinforcement member 300 may include a material having good gap filling capability so as to easily fill a narrow gap. For example, the first reinforcement member 300 may include, but not limited to, photo sensitive polyimide (PSPI), polyimide (PI), photo sensitive polyhydroxystyrene, etc.

For example, the first reinforcement member 300 may be formed to contact a lower portion of the side surface of the second part 214 of the first lower bump 210, but example embodiments are not limited thereto. For example, the first reinforcement member 300 may entirely surround the side surfaces of the second part 214 of the first lower bump 210. In the event that the first lower bump 210 is substantially completely surrounded by the first reinforcement member 300, the first lower bump 210 may not be exposed to the outside. While FIGS. 1 and 2 show that the first reinforcement member 300 completely overlap the first contact pad 110, example embodiments are not limited thereto.

Referring to FIGS. 1 and 2, the first reinforcement member 300 may be formed along the vicinity of the first conductive pattern 230. When the first bump 200 has a circular planar shape, the first reinforcement member 300 may have an annular planar shape along the circumference. In detail, the first reinforcement member 300 may be formed on the first conductive pattern 230 and may contact the side surface of the first lower bump 210 along the circumference thereof.

Referring to FIGS. 2 and 3A, the second part 214 of the first lower bump 210 may have a pillar shape. The pillar-shaped second part 214 may have a first surface 214a facing the insulation layer 120, a side surface 214c, and a second surface 214b connecting the first surface 214a and the side surface 214c. The first surface 214a of the second part 214 facing the insulation layer 120 may contact the first conductive pattern 230. Specifically, the first surface 214a of the second part 214 may contact the upper conductive portion 234 of the first conductive pattern 230. Referring to FIG. 3A, the second surface 214b of the second part 214 may have a slope continuously increasing from the first surface 214a of the second part 214 to the side surface 214c of the second part 214, but example embodiments are not limited thereto.

A cross-section between the second surface 214b of the second part 214 and the insulation layer 120, which lie on the upper conductive portion 234, may have a wedge shape. A portion of the first reinforcement member 300 may be interposed between the second surface 214b of the second part 214 and the insulation layer 120 (or the upper conductive portion 234).

Referring to FIG. 3A, a width of the first reinforcement member 300 is greater than a value obtained by dividing by 2 a difference between the width w3 of the first conductive pattern 230 and the width w2 of the second part 214 of the first lower bump 210. A length ranging from a location where the first surface 214a of the second part 214 and the second surface 214b of the second part 214 meet from an edge of the upper conductive portion 234 may be substantially the same as the width of the first reinforcement member 300. The expression “the same width” used herein may mean that widths of two locations compared are completely equal to each other and may encompass a negligible difference in the width, which may be caused due to a processing margin.

The first reinforcement member 300 may commonly contact the second surface 214b of the second part 214 and the side surface 214c of the second part 214, but example embodiments are not limited thereto. That is to say, the first reinforcement member 300 may contact only the second surface 214b of the second part 214 and the upper conductive portion 234 according to the amount of the first reinforcement member 300 and the forming process of the first reinforcement member 300.

Referring to FIGS. 2, 3B and 3C, a portion of the first reinforcement member 300 may not overlap the first conductive pattern 230, specifically the upper conductive portion 234. That is to say, not only the first conductive pattern 230 but also a different material from the first conductive pattern 230 or an air gap may be formed under the first reinforcement member 300. In other words, the first conductive pattern 230 may be undercut to a lower portion of the first reinforcement member 300.

A non-overlapping length of the first reinforcement member 300 and the upper conductive portion 234 may be denoted by d. The non-overlapping length d of the first reinforcement member 300 and the upper conductive portion 234 may vary according to the forming process of the first conductive pattern 230. For example, the non-overlapping length d of the first reinforcement member 300 and the upper conductive portion 234 may vary according to the thickness of the first conductive pattern 230, the concentration of an etching solution used in dry etching or wet etching to form the first conductive pattern 230.

If the first bump 200, the first reinforcement member 300 and the first conductive pattern 230 are concentrically formed, the circumference of the first conductive pattern 230 may be positioned between the first bump 200 and the first reinforcement member 300. A radial difference between the first reinforcement member 300 and the first conductive pattern 230 corresponds to the non-overlapping length d of the first reinforcement member 300 with respect to the upper conductive portion 234. For example, the width of the removed (e.g., undercut) portion of the first conductive pattern 230 under the first reinforcement member 300 may correspond to the non-overlapping length d of the first reinforcement member 300 with respect to the upper conductive portion 234.

FIG. 4 illustrates a semiconductor device according to other example embodiments.

These example embodiments are substantially the same as the previous example embodiments, except for widths of a first conductive pattern and a first lower bump. Thus, the same portions are denoted by the same reference numeral and explanations thereof will be briefly made or may be omitted.

Referring to FIG. 4, the semiconductor device 2 may include a substrate 100, a first contact pad 110, a first bump 200 and a first reinforcement member 300. The semiconductor device 2 may further include an insulation layer 120 and/or a first conductive pattern 230.

The first contact pad 110 may be formed on one surface 100a of the substrate 100. The insulation layer 120 may cover the one surface 100a of the substrate 100 and a first contact pad 110. The insulation layer 120 may include a first opening 120t exposing at least a portion of the first contact pad 110. The first conductive pattern 230 may be conformally formed along the insulation layer 120 and the first opening 120t and may include a lower conductive portion 232 and a upper conductive portion 234. The first bump 200 formed on the first contact pad 110 may include a first upper bump 220 and a first lower bump 210. Further, the first lower bump 210 may include a first part 212 and a second part 214. The first part 212 of the first lower bump 210 may be formed in the first opening 120t, and the second part 214 of the first lower bump 210 may be formed to be higher than the upper conductive portion 234. The first reinforcement member 300 may be formed on the insulation layer 120 and may surround the first lower bump 210.

Referring to FIG. 4, a width w3 of the first conductive pattern 230 may be smaller than a width w2 of the second part 214 of the first lower bump 210. Accordingly, the width w3 of the first conductive pattern 230 may be smaller than the width w2 of the first lower bump 210. The first conductive pattern 230 may substantially completely overlap the first bump 200. A surface of the second part 214 of the first lower bump 210 facing the insulation layer 120 may contact the upper conductive portion 234 and the first reinforcement member 300.

The first conductive pattern 230 may be removed under the second part of the first lower bump 210, thereby forming an undercut region 233. The first reinforcement member 300 may be formed on a side surface of the first lower bump 210, and a portion of the first reinforcement member 300 may be inserted into the undercut region 233. The first reinforcement member 300 inserted into the undercut region 233 may contact the upper conductive portion 234.

The first reinforcement member 300 may be formed along the lower portion of the side surface of the second part 214 of the first lower bump 210. The first reinforcement member 300 may contact not only the first lower bump 210 and the upper conductive portion 234 but also the insulation layer 120.

As shown in FIG. 4, an angle formed between the surface of the second part 214 of the first lower bump 210 facing the insulation layer 120 and the side surface of the second part 214 may be a substantially right angle, but example embodiments are not limited thereto.

As shown in FIGS. 3A and 3B, a surface 241b having a continuously increasing slope may be formed between the surface 214a of the second part 214 of the first lower bump 210 facing the insulation layer 120 and the side surface 214c of the second part 214.

Next, effects obtained by forming the reinforcement member surrounding the bump will be described.

The formation of the reinforcement member surrounding the lower portion of the side surface of the bump, specifically, the lower bump, may allow the bump formed on the substrate to be more tightly combined with the substrate, thereby reducing a pitch between bumps.

The undercut region 233, at which the conductive pattern is removed under the second part 214 of the first lower bump 210, may be filled with the reinforcement member, thereby preventing the upper bump from being wet to the side surface of the lower bump in a subsequent process.

The formation of the reinforcement member surrounding the lower portion of the side surface of the lower bump may prevent the conductive pattern from being etched, thereby preventing or suppressing a width of the conductive pattern from being reduced, ultimately improving the reliability of the semiconductor package.

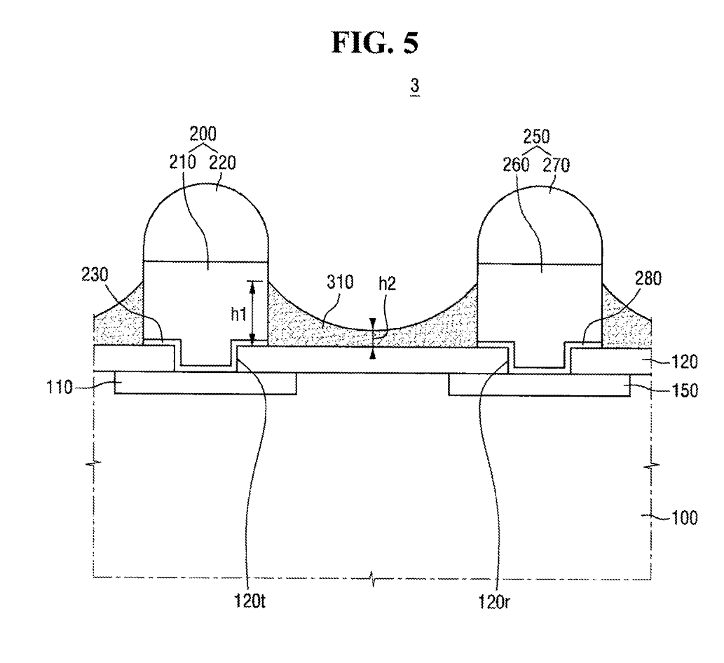

FIG. 5 is a plan view illustrating a portion of a semiconductor device according to still other example embodiments.

Referring to FIG. 5, the semiconductor device 3 may include a substrate 100, a plurality of contact pads 110 and 150, a plurality of bumps 200 and 250 and a second reinforcement member 310.

The first contact pad 110 and the second contact pad 150 may be formed on one surface of a substrate 100 and be spaced apart from each other. An insulation layer 120 formed on the substrate 100 may include a first opening 120t and a second opening 120r exposing at least a portion of the first contact pad 110 and the second contact pad 150, respectively. The first conductive pattern 230 and the second conductive pattern 280 may be conformally formed on the first opening 120t and the second opening 120r, respectively. The first bump 200 and the second bump 250 may be formed on the first contact pad 110 and the second contact pad 150, respectively, and be spaced apart from each other. The first bump 200 may include a first upper bump 220 and a first lower bump 210, and the second bump 250 may include a second upper bump 270 and a second lower bump 260.

The second reinforcement member 310 may be formed to surround the first lower bump 210 and the second lower bump 260. The second reinforcement member 310 may physically connect the first lower bump 210 to the second lower bump 260. Because the second reinforcement member 310 may be also formed on the insulation layer 120 between the first bump 200 and the second bump 250, the second reinforcement member 310 may cover the insulation layer 120 between the first bump 200 and the second bump 250.

A first height h1 may be a height of the second reinforcement member 310 from the insulation layer 120 at a position where the second reinforcement member 310 contact the first lower bump 210 (or second lower bump 260) of the first bump 200 (or second bump 250). A second height h2 may be a lowest height of the second reinforcement member from the insulation layer 120 at a middle position between the first lower bump 210 and the second lower bump 260. For example, the first height h1 may be greater than the second height h2. For example, a cross-section of the second reinforcement member 310 may have an arch shape. Thus, the second reinforcement member 310 may be convex in a direction toward the substrate 100. Accordingly, a thickness of the second reinforcement member 310 may be reduced as being farther away from, for instance, both of the first lower bump 210 and the second lower bump 260. Although a cross-section of the second reinforcement member 310 may be shaped of, for example, an arch, but not example embodiments are not limited thereto.

According to a plan view of the semiconductor device 3, the second reinforcement member 310 may completely cover the insulation layer 120, except for areas at which the first bump 200 and the second bump 250 protruding through the second reinforcement member 310. Accordingly, the first bump 200 and the second bump 250 may be a plurality of islands protruding from the second reinforcement member 310.

In FIG. 5, a width of the first conductive pattern 230 is substantially the same as that of the first lower bump 210 and a width of the second conductive pattern 280 is substantially the same as that of the second lower bump 260, but example embodiments are not limited thereto. For example, the first conductive pattern 230 may be undercut under a lower portion of the first lower bump 210, and the second conductive pattern 280 may be undercut under a lower portion of the second lower bump 260.

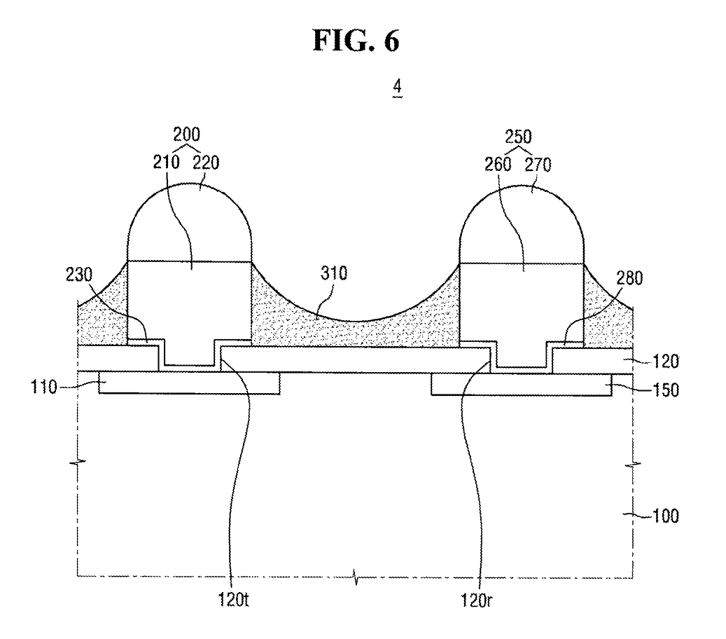

A semiconductor device according to even other example embodiments will be described with reference to FIG. 6. These embodiments are substantially the same as the previous example embodiments shown in FIG. 5, except for a height of a reinforcement member, and the following description will focus on differences between the present example embodiments and the previous example embodiments.

FIG. 6 illustrates a semiconductor device according to even other example embodiments.

Referring to FIG. 6, the semiconductor device 4 may include a substrate 100, a plurality of contact pads 110 and 150, a plurality of bumps 200 and 250 and a second reinforcement member 310.

The second reinforcement member 310 may entirely surround side surfaces of the first lower bump 210 and the second lower bump 260. For example, the second reinforcement member 310 may be entirely formed on the side surfaces of the first lower bump 210 and the second lower bump 260 by adjusting heights of the first lower bump 210 and the second lower bump 260 or by adjusting a height of the second reinforcement member.

The first conductive pattern 230 may be undercut under a lower portion of the first lower bump 210, and the second conductive pattern 280 may be undercut under a lower portion of the second lower bump 260.

If the second reinforcement member 310 entirely surrounds the side surfaces of the first lower bump 210 and the second lower bump 260, a running down phenomenon of the first upper bump 220 and the second upper bump 270 may be reduced or prevented, thereby improving co-planarity of the first bump 200 and the second bump 250. Further, a formation of an intermetallic compound on the side surfaces of the lower bumps 210 and 260, due to the metallic element(s) in the upper bumps 220 and 270, may be prevented or reduced, thereby improving the reliability of the first bump 200 and the second bump 250.

Referring to FIG. 6, the second reinforcement member 310 may physically connect multiple bumps 200 and 250 to each other such that the second reinforcement member 310 may entirely surround the side surfaces of the first lower bump 210 and the second lower bump 260. However, example embodiments are not limited thereto. For example, the second reinforcement member 310 may not physically connect the first bump 200 to the second bump 250.

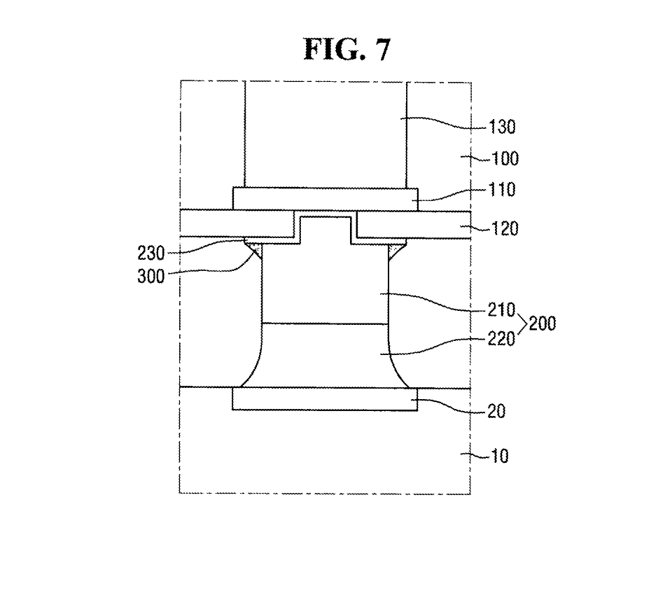

FIG. 7 illustrates a state in which semiconductor devices according to example embodiments are adhered to different substrates.

Specifically, FIG. 7 is an enlarged view illustrating a state in which bumps of the semiconductor devices according to example embodiments are adhered to pads formed on different substrates.

Referring to FIG. 7, a first contact pad 110 formed on a first substrate 100 may be connected to a through electrode 130, which is formed penetrate the first substrate 100. However, the first contact pad 110 is not limited as being connected to the through electrode 130. The first bump 200 on the first contact pad 110 may be electrically connected to a third contact pad 20 formed on the second substrate 10. The first upper bump 220 of the first bump 200 may be wet to the third contact pad 20, thereby electrically connecting the first substrate 100 to the second substrate 10.

The second substrate 10 may be, for example, a mounting substrate for mounting a semiconductor chip, or a semiconductor chip incorporating a semiconductor device, but example embodiments are not limited thereto.

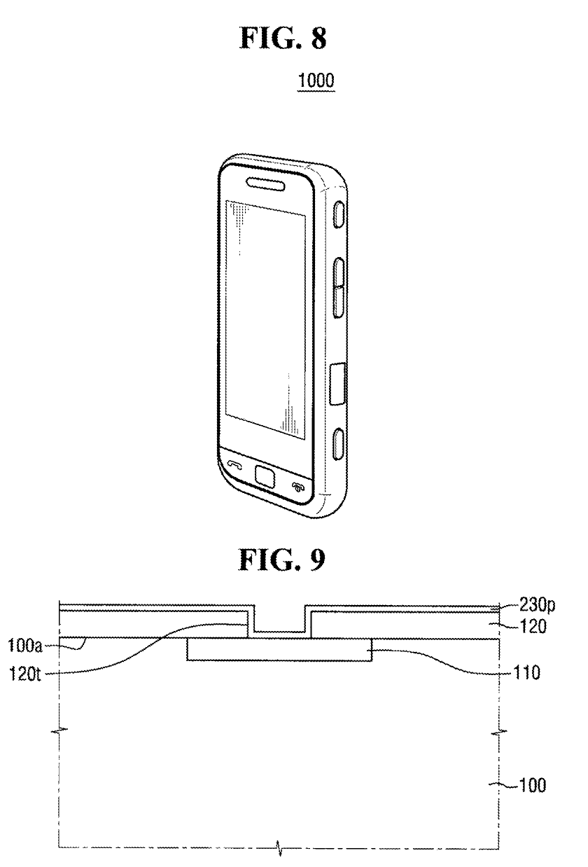

FIG. 8 is a perspective view of an electronic device including semiconductor devices manufactured according to various example embodiments.

Referring to FIG. 8, semiconductor devices manufactured according to various example embodiments may be applied to an electronic device 1000, such as a mobile phone. Because the semiconductor devices manufactured according to various example embodiments are highly reliable, the operating reliability of the semiconductor devices can be improved or ensured even if the electronic device 1000 is used under severe conditions. The electronic device 1000 may not limited to the mobile phone shown in FIG. 7, and may be various electronic devices, including a mobile electric device, a notebook computer, a portable multimedia player (PMP), an MP3 player, a camcorder, a memory stick, a memory card, etc.

A method for fabricating a semiconductor device according to an embodiment of the present invention will now be described with reference to FIGS. 9 to 14.

FIGS. 9 to 14 illustrate intermediate process steps for explaining a method for fabricating a semiconductor device according to example embodiments

Referring to FIG. 9, a substrate 100 having a first contact pad 110 formed on its one surface 100a may be provided. A first contact pad 110 formed on the one surface 100a of the substrate 100 and a pre-insulation layer (not shown) covering the one surface 100a of the substrate 100 may be formed. A portion of the pre-insulation layer may be removed by photolithography and etching, thereby forming an insulation layer 120 including a first opening 120t. The first opening 120t may expose at least a portion of the first contact pad 110.

A conductive film 230p may be conformally formed on the one surface 100a of the substrate 100. The conductive film 230p may be formed on the insulation layer 120 and the first opening 120t. The conductive film 230p may also be formed on the first contact pad 110 exposed by the first opening 120t. The conductive film 230p may be formed by, for example, sputtering.

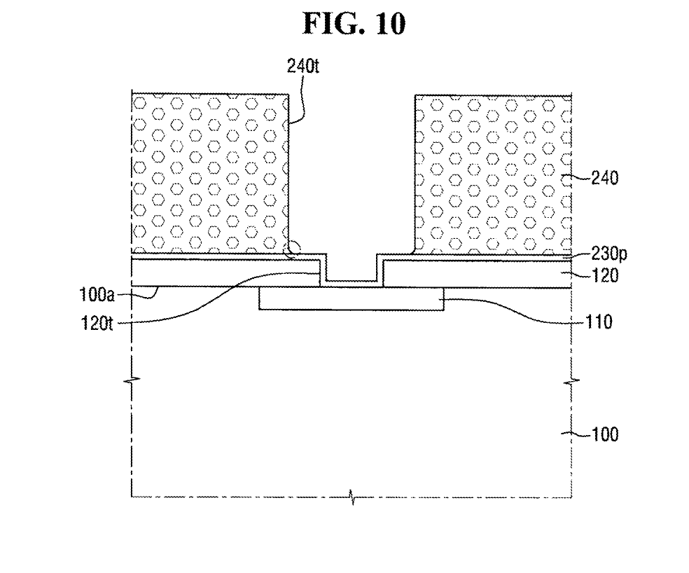

Referring to FIG. 10, a photoresist film pattern 240 including a third opening 240t may be formed on the conductive film 230p. The third opening 240t may be formed on the first contact pad 110, and the conductive film 230p formed on the first contact pad 110 may be exposed. A width of the first opening 120t may be smaller than that of the third opening 240t. The first opening 120t may substantially completely overlap the third opening 240t.

A boundary portion indicated by a dotted circle in FIG. 10 may be a portion where the third opening 240t and the conductive film 230p meet. This boundary portion formed by a sidewall of the third opening 240t and the conductive film 230p may be, for example, a curved line or a straight line having a predetermined or desired slope, rather than a right angle. For example, a photoresist footing may remain at the boundary portion where the third opening 240t and the conductive film 230p meet boundary. Although the boundary between the sidewall of the third opening 240t and the conductive film 230p is indicated by a curve line in FIG. 10 for convenience of illustration, example embodiments are not limited thereto.

The photoresist film pattern 240 may include, for example, a positive photoresist or a negative photoresist. The photoresist may include various materials according to kinds of light sources used in an exposure process or shapes of patterns to be formed. Examples of the light source may include, ArF (193 nm), KrF (248 nm), EUV (Extreme Ultra Violet), VUV (Vacuum Ultra Violet, 157 nm), an E-beam, X-ray or an ion beam, but example embodiments are not limited thereto.

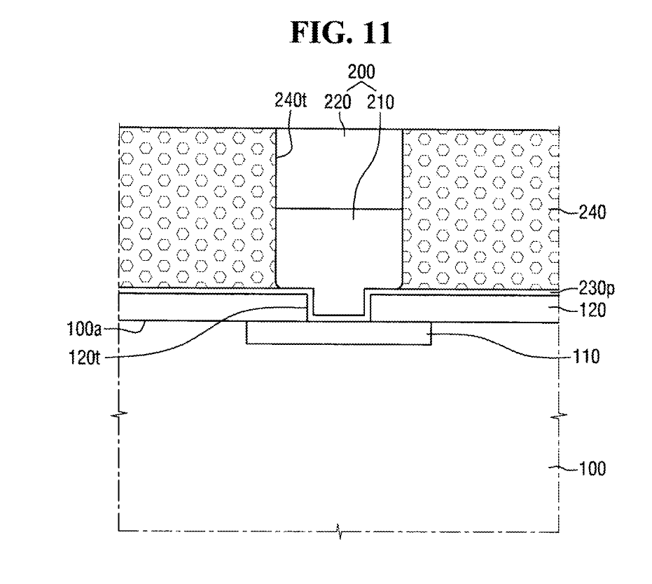

Referring to FIG. 11, the first bump 200 may be formed on the conductive film 230p. The first bump 200 may overlap the first contact pad 110, and may include a first lower bump 210 and a first upper bump 220 sequentially stacked on the first contact pad 110. The first opening 120t and the third opening 240t may be filled with the conductive material, thereby sequentially forming the first lower bump 210 and the first upper bump 220.

For example, the photoresist film pattern 240 including the third opening 240t may be formed on the substrate 100, and a surface of the conductive film 230p exposed by the third opening 240t may be then be washed. The surface of the conductive film 230p may be washed by, for example, a descum process, which is one of dry etching methods. The first lower bump 210 may be formed on the washed conductive film 230p. The first lower bump 210 may fill the first opening 120t and a portion of the third opening 240t. The first lower bump 210 may be formed by, for example, electroplating. After the first lower bump 210 is formed, the remaining portion of the third opening 240t may be filled, thereby forming the first upper bump 220 on the first lower bump 210. The first upper bump 220 may be formed by, for example, electroplating.

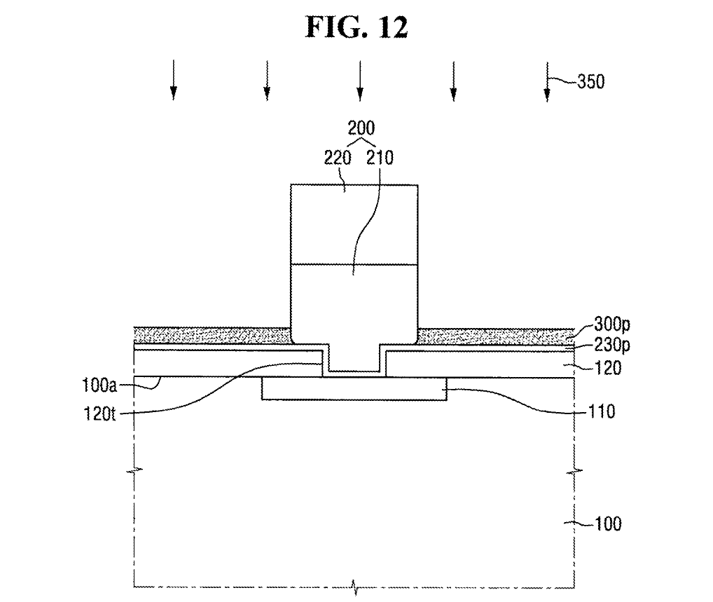

Referring to FIG. 12, the first reinforcement film 300p surrounding the first bump 200 may be formed on the conductive film 230p, thereby covering the conductive film 230p.

For example, after forming the first bump 200, the photoresist film pattern 240 may be removed. After removing the photoresist film pattern 240, the first bump 200 protruding from the conductive film 230p may remain on the substrate 100. After removing the photoresist film pattern 240, the first reinforcement film 300p covering the conductive film 230p may be formed on the substrate 100 to surround the first bump 200. The first reinforcement film 300p may be formed on the conductive film 230p by, for example, coating.

Although the first reinforcement film 300p is not formed on the first upper bump 220 in FIG. 12, example embodiments are not limited thereto.

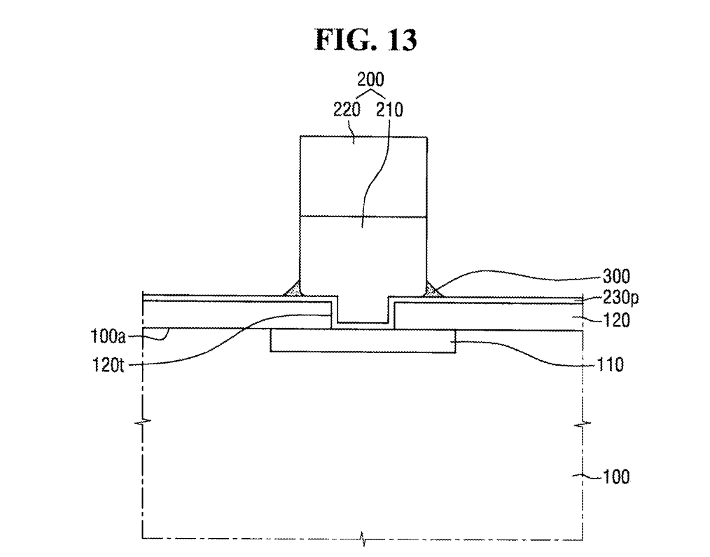

Referring to FIGS. 12 and 13, the first reinforcement member 300 surrounding the first lower bump 210 may be formed. The first reinforcement member 300 may be formed on the conductive film 230p. The first reinforcement member 300 may be formed at a lower portion of the side surface of the first lower bump 210, but example embodiments are not limited thereto.

For example, after forming the first reinforcement film 300p, a first exposure process 350 may be performed. By performing the first exposure process 350, the reinforcement film 300p may be removed except for a portion or portions of the first reinforcement film 300p adjacent to or around the first lower bump 210. Thus, after performing the first exposure process 350, only a portion or portions of the first reinforcement film 300p surrounding the first lower bump 210 may selectively remain, thereby forming the first reinforcement member 300 surrounding the first lower bump 210.

The first exposure process 350 may be performed using, for example, a phase shift mask. The use of the phase shift mask may allow exposed light amounts around the first bump 200 and the first bump 200 to be adjusted to be smaller than those of the other portions. As the result, only a portion or portions of the first reinforcement film 300p surrounding (around, or adjacent to) the first lower bump 210 may remain, while the remaining portion of the first reinforcement film 300p is removed.

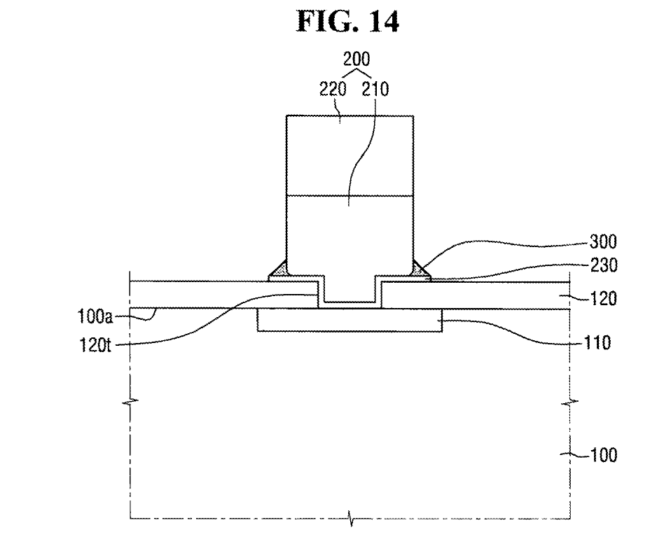

Referring to FIG. 14, a portion of the conductive film 230p not overlapping the first reinforcement member 300 and the first bump 200 may be removed, thereby forming the first conductive pattern 230 on the insulation layer 120. A portion of the conductive film may be removed by, for example, wet etching. A conductive film not overlapping the first reinforcement member 300 and the first bump 200 may be removed, thereby securing the first bump 200 to be electrically insulated from other bumps on the substrate.

After forming the first conductive pattern 230, a reflow process may be performed, thereby forming the outer surface of the first upper bump 220 into a curved surface.

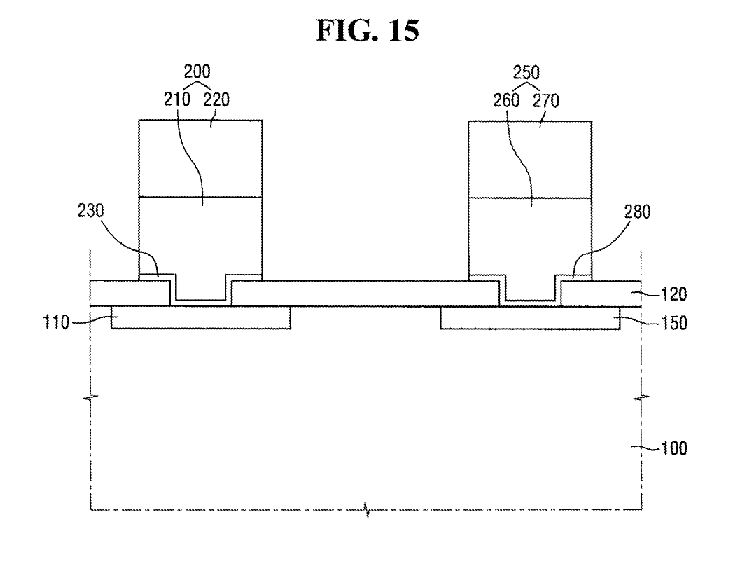

A method for fabricating a semiconductor device according to other example embodiments will be described with reference to FIGS. 15 to 17.

FIGS. 15 to 17 illustrate intermediate process steps for explaining a method for fabricating a semiconductor device according to other example embodiments.

Referring to FIG. 15, a substrate 100 having a first contact pad 110 and a second contact pad 150 spaced apart from each other may be provided. An insulation layer 120 may be formed on the substrate 100 and may expose at least a portion of each of the first contact pad 110 and the second contact pad 150. A conductive film (not shown) may be conformally formed on the insulation layer 120. Thereafter, a first bump 200 may be formed on the first contact pad 110, and a second bump 250 may be formed on the second contact pad 150. The first bump 200 may include a first lower bump 210 and a first upper bump 220, and the second bump 250 may include a second lower bump 260 and a second upper bump 270.

After forming the first bump 200 and the second bump 250 spaced apart from each other, a portion of the conductive film is removed, thereby forming a first conductive pattern 230 and a second conductive pattern 280. The first conductive pattern 230 and the second conductive pattern 280 may be formed to be spaced apart from each other.

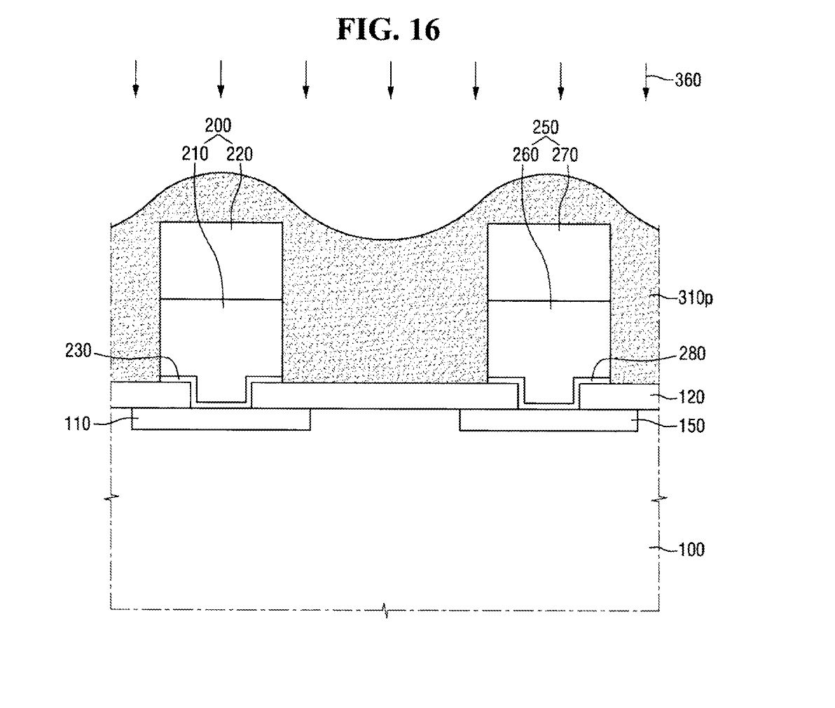

Referring to FIG. 16, a second reinforcement layer 310p covering the first bump 200 and the second bump 250 may be formed on the insulation layer 120. In FIG. 16, the second reinforcement layer 310p is curved according to the first bump 200 and the second bump 250, but example embodiments are not limited thereto. For example, a top surface of the second reinforcement layer 310p may be planar.

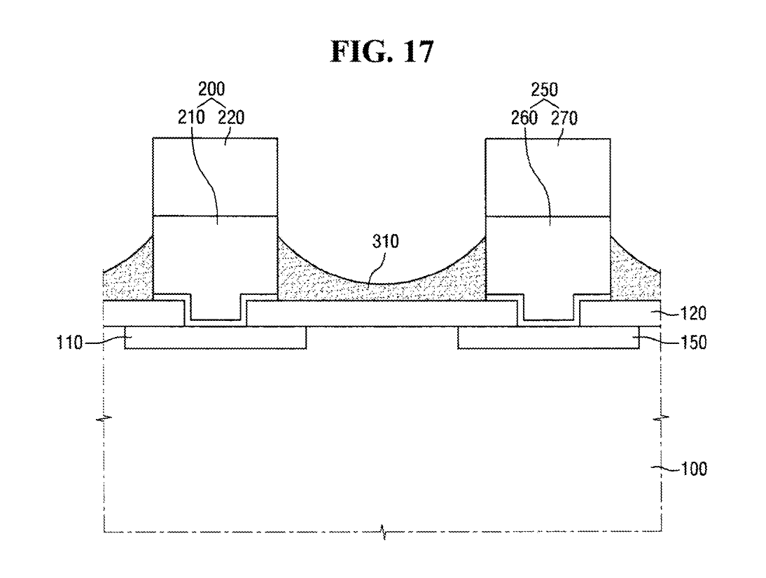

Referring to FIGS. 16 and 17, after forming the second reinforcement layer 310p, a second exposure process 360 may be performed. By performing the second exposure process 360, a portion of the second reinforcement layer 310p covering the first bump 200 and the second bump 250 may be removed, thereby allowing the first upper bump 220 and the second upper bump 270 to protrude on the second reinforcement layer 310p. Accordingly, a second reinforcement member 310 connecting the first lower bump 210 and the second lower bump 260 may be formed.

Referring to FIG. 17, the second reinforcement member 310 may connect the first lower bump 210 and the second lower bump 260 to each other. The insulation layer 120 positioned between the first bump 200 and the second bump 250 may be covered by the second reinforcement member 310 so that the insulating layer 120 is not exposed to the outside.

While example embodiments have been particularly shown and described with reference to the present example embodiments, it will be understood by those of ordinary skill in the art that various changes in form and details may be made therein without departing from the spirit and scope of example embodiments defined by the following claims. It is therefore desired that the present example embodiments be considered in all respects as illustrative and not restrictive.

What is claimed is:

1. A semiconductor device comprising:
a substrate;
a first contact pad on the substrate;
an insulation layer on the substrate, the insulation layer including a first opening which exposes the first contact pad;
a first bump on the first contact pad and electrically connected to the first contact pad, the first bump including a first lower bump and a first upper bump; and
a reinforcement member on the insulation layer and adjacent to a side surface of the first lower bump.

2. The semiconductor device of claim 1, wherein the first lower bump includes a first part having a first width and a second part having a second width, the second width greater than the first width, the first part filling the first opening, and the second part being higher than the insulation layer and surrounded by the reinforcement member.

3. The semiconductor device of claim 2, wherein the second part has a pillar shape, and includes a first surface facing the insulation layer, and a second surface connecting the first surface to a side surface of the second part.

4. The semiconductor device of claim 3, wherein a cross-section between the second surface and the insulation layer is wedge-shaped, and a portion of the reinforcement member is interposed between the second surface and the insulation layer.

5. The semiconductor device of claim 2, wherein the reinforcement member contacts a lower portion of the side surface of the second part.

6. The semiconductor device of claim 1, further comprising:
a first conductive pattern interposed between the first bump and the first contact pad, the first conductive pattern conformally formed along the insulation layer and the first opening.

7. The semiconductor device of claim 6, wherein a width of the first conductive pattern is greater than that of the first lower bump, the reinforcement member on the first conductive pattern, and being around and in contact with the first lower bump.

8. The semiconductor device of claim 7, wherein a portion of the reinforcement member does not overlap the first conductive pattern.

9. The semiconductor device of claim 6, wherein the first conductive pattern is partially removed under a lower portion of the first lower bump to form an undercut region, and a portion of the reinforcement member is inserted into the undercut portion of the first conductive pattern, and contacts the first conductive pattern.

10. The semiconductor device of claim 1, further comprising:
a second contact pad formed on the substrate, the second contact pad spaced apart from the first contact pad; and
a second bump on the second contact pad, the second bump including a second lower bump and a second upper bump,
wherein the reinforcement member connects the first lower bump to the second lower bump.

11. The semiconductor device of claim 10, wherein the reinforcement member is convexly formed toward the substrate.

12. A semiconductor device comprising:
a substrate;
a contact pad formed on the substrate;
a bump on the contact pad;
a conductive pattern interposed between the contact pad and the bump, the conductive pattern having a portion exposed from the bump; and
a reinforcement member on the exposed portion of the conductive pattern and at a lower portion of a side surface of the lower bump.

13. The semiconductor device of claim 12, wherein the bump has a first width, the conductive pattern has a second width, and the first width is greater than the second width.

14. The semiconductor device of claim 12, wherein the reinforcement member contacts a lower portion of the side surface of the bump and is around the conductive pattern.

15. The semiconductor device of claim 12, wherein a portion of the reinforcement member does not overlap the conductive pattern.

16. A semiconductor device comprising:
a contact pad on a substrate;
an insulation layer on a substrate, the insulation layer including an opening which exposes the contact pad;
a bump electrically connecting the contact pad through the opening;
a reinforcement member on the insulation layer, the reinforcement layer adjacent to a side surface of the bump and on the insulation layer.

17. The semiconductor device of claim 16, further comprising:
a conductive pattern under the reinforcement member and along the insulation layer and the opening, the conductive pattern including a non-overlap portion with respect to the reinforcement member, the reinforcement member on the non-overlap portion of the conductive pattern.

18. The semiconductor device of claim 16, further comprising:
a conductive pattern under the reinforcement member and along the insulation layer and the opening, the conductive pattern defining an undercut region in association with the bump and insulating layer.

19. The semiconductor device of claim 16, wherein the bump includes a lower bump and an upper bump, and the reinforcement member is adjacent to at least a lower portion of a side surface of the lower bump.

20. The semiconductor device of claim 19, wherein the lower bump includes a first part filling the opening and a second part on the first part, the first and second parts defined with respect to an upper surface of the insulation layer, and the reinforcement member adjacent to at least a lower portion of a side surface of the second part.
